(19) United States
(12) Patent Application Publication
(10) Pub. No.: US 2006/0030087 A1
(43) Pub. Date: Feb. 9, 2006

(54) Compliant substrate for a heteroepitaxial structure and method for making same

(75) Inventor: Takeshi Akatsu, Saint Nazaire Les Eymes (FR)

Correspondence Address: WINSTON & STRAWN LLP, 1700 K STREET, N.W., WASHINGTON, DC, 20006, US

(73) Assignee: S.O.I.TEC SILICON ON INSULATOR TECHNOLOGIES, S.A.

(21) Appl. No.: 11/224,078

(22) Filed: Sep. 13, 2005

Related U.S. Application Data
(62) Division of application No. 10/753,171, filed on Jan. 6, 2004.
(60) Provisional application No. 60/472,400, filed on May 22, 2003.

(30) Foreign Application Priority Data
Jan. 10, 2003 (EP) 03290072.2

(51) Int. Cl. H01L 21/84

(52) U.S. Cl. 438/149

(57) ABSTRACT

The present invention relates to a compliant substrate having a top surface for receiving a heteroepitaxial structure or heteroepitaxial layer. This substrate comprises a carrier substrate, a top single-crystalline layer, a buried layer located between the carrier substrate and the top layer, and a weakened region located in the top layer or between the top layer and the buried layer such that the compliant substrate facilitates relaxed growth of a heteroepitaxial layer or structure upon the top surface. The invention also relates to the combination of the compliant substrate and a heteroepitaxial layer provided thereon, as well as to a method of making the compliant substrate and combination.

This application is a division of U.S. patent application Ser. No. 10/753,171, filed Jan. 6, 2004, which claims the benefit of U.S. Provisional Application No. 60/472,400, filed May 22, 2003, the entire content of which applications is expressly incorporated herein by reference thereto.

### FIELD OF THE INVENTION

The present invention relates to a compliant substrate for a heteroepitaxial structure and a method for fabricating the compliant substrate.

### BACKGROUND ART

A compliant substrate is a type of a substrate that has been engineered in such a way as to accommodate the strain that results from heteroepitaxial growth of a material that has a lattice parameter that is different from the substrate.

WO 99/39377 describes a compliant substrate consisting of a silicon wafer having in a very small depth of the wafer a layer of microcavities being generated by hydrogen ion implantation into the silicon wafer. The thin silicon layer formed above the implanted region acts as a compliant layer on which a heteroepitaxial layer can be deposited.

WO 99/39377 further mentions a prior art technology using a SOI (silicon-on-insulator) structure to provide a compliance effect for a heteroepitaxial structure on top of the SOI structure. The authors of this document state that it is not recommended to use SOI structures as compliant substrates because several further process steps such as thermal treatments at higher temperatures and/or boron or phosphorus implantations of the SiO₂ layer of the SOI-substrate are necessary to achieve sufficient compliance of the SOI-substrate. In particular, these thermal treatments are frequently incompatible with the epitaxial layer so that a sufficient compliance cannot be provided.

Both of the above approaches are not able to provide a compliance which is sufficient enough for producing a low stress and high quality heteroepitaxial layer on the respective substrates.

There remains a need to provide a compliant substrate, a heteroepitaxial structure and a method for providing a compliant substrate, where a heteroepitaxial layer can be brought onto a compliant substrate with a very low defect rate and a high rate of reproduction and efficiency. The present invention now satisfies this need.

### SUMMARY OF THE INVENTION

The invention relates to a compliant substrate having a top surface for receiving a heteroepitaxial structure or heteroepitaxial layer. This substrate comprises a carrier substrate, a top single-crystalline layer, a buried layer located between the carrier substrate and the top layer, and a weakened region located in the top layer or between the top layer and the buried layer such that the compliant substrate facilitates relaxed growth of a heteroepitaxial layer or structure upon the top surface.

The weakened region can form an interface between the buried layer and the top layer, or can be located in the top layer, or it can include a first weakened region that forms an interface between the buried layer and a second weakened region located in the top layer. Advantageously, the weakened region contains implanted species, such as hydrogen or rare gas ions. The buried layer is generally an amorphous layer or a porous layer, such as silicon dioxide.

The invention also provides a heteroepitaxial structure of the compliant substrate and a single-crystalline epitaxial layer provided on the top surface thereof, wherein the epitaxial layer has a lattice constant that is different from that of the top layer.

In another embodiment, the invention relates to a method for making a compliant substrate to receive a heteroepitaxial structure. This method comprises preparing a base structure that comprises a carrier substrate, a top single-crystalline layer that provides a top surface for the base structure, a buried layer located between the carrier substrate and the top layer; and providing a weakened region in the top layer or between the top layer and the buried layer to form the compliant substrate.

### BRIEF DESCRIPTION OF THE DRAWING FIGURES

Other characteristics and advantages of the invention become apparent from the following description of a preferred implementation of the invention. This description is made with reference to the accompanying drawings in which:

FIG. 1 shows schematically a side view of a compliant substrate according to an embodiment of the invention;

FIG. 2 shows schematically a side view of a heteroepitaxial structure according to an embodiment of the invention;

FIGS. 3 to 5 show schematically an exemplary process flow of a first embodiment of the inventive method for fabricating a compliant substrate as shown in FIG. 1;

FIGS. 6 to 8 show schematically an exemplary process flow of a second embodiment of the inventive method for fabricating a compliant substrate as shown in FIG. 1; and

FIG. 9 shows schematically a growth and an annealing of a second heteroepitaxial layer on a compliant substrate, resulting in a heteroepitaxial structure as shown in FIG. 2.

### DETAILED DESCRIPTION OF PREFERRED EMBODIMENTS

The present invention provides a compliant substrate for a heteroepitaxial structure or layer, which allows the heteroepitaxial layer to be brought onto the compliant substrate with a very low defect rate and a high rate of reproduction and efficiency. The compliant substrate according to the present invention comprises: a carrier substrate; a buried layer; a single-crystalline top layer; and at least one weakened region. The weakened region includes a first region at or near an interface between the buried layer and the top layer and/or a second region in the top layer.

The compliant substrate according to the present invention provides a very good slippage between the top layer and the buried layer and good isolation from the carrier substrate due to the buried layer therebetween. This allows a low stress growth of an epitaxial layer on the compliant substrate with a high efficiency. The substrate makes it possible for a heteroepitaxial structure to be produced on the top surface of the top layer in the form of a relatively thick but relaxed heteroepitaxial layer.

As compared to the prior art, the compliant substrate of the present invention provides a new quality of stress adaptation. In particular, the region at or near the interface between the buried layer and the top layer can be weakened exceedingly so that this weakened layer can provide a very high compliance effect. This effect will further be achieved or be improved by the weakening multiple regions in the top layer. The weakened region(s) can be provided in the immediate vicinity of the top surface of the compliant substrate, which makes it possible to have a better effect on the quality of the heteroepitaxial layer that is provided on that top surface. When the weakened region in the top layer acts in addition with a weakened region at or near the interface, a nearly perfect growth of a heteroepitaxial layer on the compliant substrate can be attained.

In one embodiment of the invention, the weakened region contains implanted species. These species can provide, in a simple manner, microbubbles or other microcavities in that region which allow a good slippage characteristic between the buried layer and the top layer. The species can be altered especially well in the region at or near the interface so that this species containing region can be provided with a very low thickness, resulting in an improved compliance effect between the compliant substrate and a heteroepitaxial layer on top of this substrate.

In a preferred embodiment of the invention, the implanted species are hydrogen or rare gas ions. Rare gases are elements of the Group VIII of the periodic table and comprise, e.g., helium. These species can be implanted with a high efficiency and accuracy leading to a pre-determinable depth and quantity of damages at or near the interface between the buried layer and the top layer.

According to a preferred embodiment of the invention, the buried layer is an amorphous and/or a porous layer, which decreases an adhesion force between the buried layer and the top layer, resulting in an enhanced slippage effect therebetween.

As a variant of the invention, the buried layer comprises silicon dioxide. This material can be provided efficiently on the carrier substrate and as further a good isolation characteristic, for instance with reference to a top layer comprising silicon.

Optionally, the top layer has a thickness of less than about 20 nm. This thin layer is particularly suitable for relaxed growth of a heteroepitaxial layer on top of the top layer.

The present invention further provides a heteroepitaxial structure comprising the compliant substrate and a further single-crystalline epitaxial layer on top surface of the compliant structure. This is generally provided on the top surface of the top layer. Preferably, the lattice constant of the further layer is different from that of the top layer.

This heteroepitaxial structure offers a homogeneous, low stress epitaxial layer on top of the top layer, wherein the heteroepitaxial layer can be provided with a relatively high thickness in relation to the top layer. The weakened region allows good slippage at the interface between the buried layer and the top layer, causing a nearly defect-free growth of the further or second epitaxial layer. This results in a heteroepitaxial structure with very good electronic characteristics which can be produced in a relatively simple but efficient way.

The method for making a compliant substrate for receiving a heteroepitaxial structure preferably comprises fabricating a base structure having a buried layer between a carrier substrate and a single-crystalline top layer; and weakening a region at or near an interface between the buried layer and the top layer and/or a region in the top layer.

With this method, a compliant substrate can be produced which can provide good slippage at or near the interface between the buried layer and the top layer and/or at the weakened region in the top layer, resulting in low stress growth of a heteroepitaxial layer on top of the top layer. The method has the advantage that a simple structure comprising a carrier substrate, a buried layer and a single-crystalline top layer can be used, followed by an easy weakening step, resulting in a high productivity of fabricating high quality compliant substrates for heteroepitaxial applications.

According to a preferred embodiment, the weakening step comprises implanting species in the region at or near the interface between the buried layer and the top layer and/or in the region in the top layer. In this way, the region(s) can be weakened very precisely with high efficiency. Specifically, microcavities can be generated in a pre-definable manner, achieving a particularly good weakening effect. As a significant benefit of this method, especially the species which are implanted in the region near the interface between the buried layer and the top layer will be gathered in a relatively thin region at this interface resulting in an improved compliance of the fabricated substrate.

In a further preferred embodiment of the invention, an energy and/or a depth of the species implanted in the implanting step is adjusted so that a maximum concentration of the implanted species is approximately at or near the interface between the buried layer and the top layer. By this method, in particular the interface between the buried layer and the top layer can be weakened, resulting in an enhanced slippage effect between the buried layer and the top layer.

In a special embodiment of the invention, a dose of the implanted species is about 3×10¹⁶ cm⁻². This dose provides for a good weakening effect but prevents blistering of the implanted structure.

In another embodiment of the present invention, implanting is accomplished through a thick top layer and the method further comprises a thinning of the top layer. Through the thick top layer, implanting can be targeted in a defined region so that particularly the interface between the buried layer and the top layer can be provided with the species in the implanting step. The thinning step which can be carried out after the implanting step results in a thinned top layer which can better slip on the buried layer, resulting in better absorption of a lattice mismatch between the top layer and the heteroepitaxial layer.

Advantageously, the thinning step comprises oxidation and/or etching of the top layer. Through this method, the thickness of the top layer can be decreased with a low impact on the weakened region at or near the interface between the buried layer and the top layer.

Preferably, at least one auxiliary layer is provided on the top layer prior to the weakening step. This makes it possible to achieve a precise weakening of the region at or near the interface between the buried layer and the top layer even when the top layer has a low thickness. The auxiliary layer has the advantage that it can be chosen in a manner so that it can be easily removed from the top layer.

In accordance with another embodiment of the invention, the step of providing the auxiliary layer comprises depositing a silicon dioxide layer. The silicon dioxide layer can be easily brought onto the top layer and can be easily removed later. With this layer, in particular, an implanting step can be easily made, so that precise weakening of the region at or near the interface between the buried layer and the top layer can be provided.

This step of producing the base structure may possibly comprise fabricating a silicon-on-insulator structure. These structures comprise an interface between the silicon and the insulator layer which can be easily weakened, for instance by an implantation step, so that, based on the silicon-on-insulator structure, a compliant substrate can be fabricated in a very efficient way.

In an advantageous embodiment of the present invention, the method further comprises providing a second single-crystalline epitaxial layer on the top layer, wherein a lattice constant of the deposited second layer is different from a lattice constant of the top layer resulting in a heteroepitaxial structure. This heteroepitaxial structure can be fabricated with a nearly defect-free second epitaxial layer on top of the top layer, wherein the second layer can be produced with a relatively high thickness in a way that is efficient and easily reproduced.

It is further advantageous to provide a second single-crystalline epitaxial layer on the top layer after the weakening of the region at or near the interface between the buried layer and the top layer. Using this process sequence, the second single-crystalline epitaxial layer can be provided nearly defect-free resulting in a high quality heteroepitaxial structure.

In another embodiment of the invention, the method further comprises an annealing step of the heteroepitaxial structure. This allows a desirable relaxation of the second crystalline epitaxial layer on top of the compliant substrate.

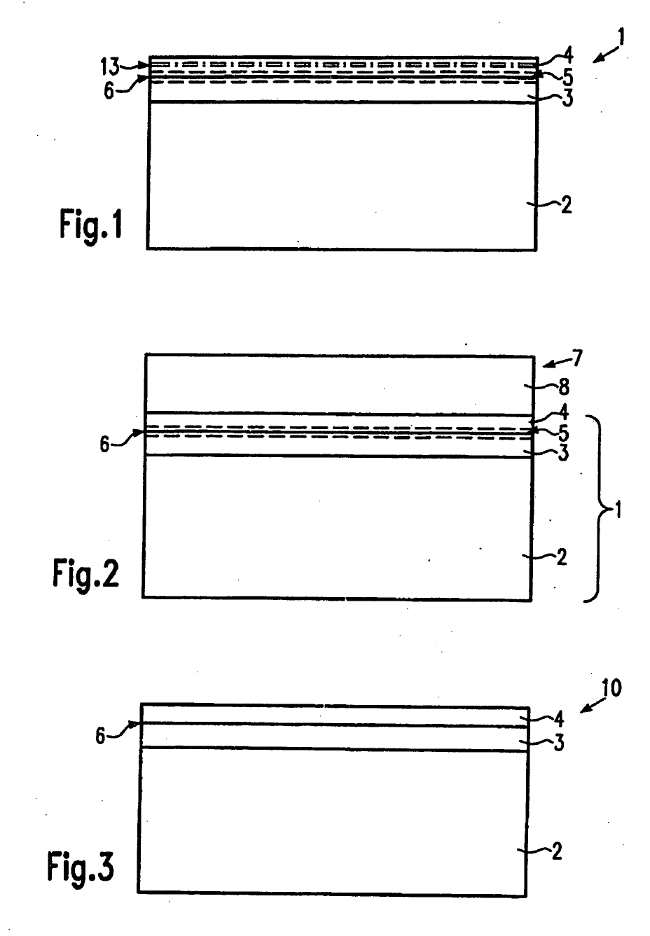

FIG. 1 shows schematically a side view of a compliant substrate 1 according to an embodiment of the invention. The compliant substrate 1 comprises a carrier substrate 2 which is, for instance, of silicon and has a thickness of several micrometers to several hundred micrometers. Besides silicon, any other material known in the art can be used as carrier substrate materials.

This carrier substrate 2 is covered by a buried layer 3. Preferably, the buried layer 3 is an amorphous and/or a porous layer, such as an insulator layer. In the embodiment shown, the buried layer 3 consists of silicon dioxide and has a thickness of about several tens of nanometers to several hundred nanometers.

On the buried layer 3 lies a single-crystalline top layer 4. In FIG. 1, the single-crystalline top layer 4 is a thin silicon layer. Preferably, the silicon layer 4 is an ultra-thin layer with a thickness of about several tens of nanometers or less. With reference to FIG. 1, the thickness of the silicon layer 4 is less than 20 nm. Instead of silicon, any other material which is different from the material of the buried layer 3 can be used as a single-crystalline top layer 4.

Between the top layer 4 and the buried layer 3 is an interface 6. In a region 5 at or near the interface 6, the material is weakened. As shown with a region 13 between the dotted-dashed lines in FIG. 1, in addition or instead of region 5, the region 13 can be weakened by implanting species in that region.

In the embodiment shown, the weakened region 5 contains preferably a layer of damages or microcavities generated by implanted species (not shown) which are included in that region 5. The implanted species can be of hydrogen or of a rare gas such as helium.

Although not explicitly shown, the regions 5 and/or 13 can be weakened with any available kind of method which is suited to affect the stability of that or these region(s).

The top layer 4 can slip or slide on the buried layer 3 due to the different material characteristics of the top layer 4 and the buried layer 4 and additionally due to the weakened region 5 which enhances the slippage effect between the top layer 4 and the buried layer 3.

FIG. 2 shows schematically a side view of a heteroepitaxial structure 7, according to an embodiment of the invention. The heteroepitaxial structure 7 contains a compliant substrate 1 such as the compliant substrate 1 of FIG. 1. As mentioned in detail with reference to FIG. 1, the compliant substrate 1 comprises a carrier substrate 2, a buried layer 3 and a single-crystalline top layer 4, with a weakened region 5 between the top layer 4 and the buried layer 3 at or near an interface 6 between the buried layer 3 and the top layer 4. The features of these layers or regions are the same as explained with reference to FIG. 1.

In FIG. 2, a second single-crystalline epitaxial layer 8 is on top of the top layer 4. The second single-crystalline epitaxial layer 8 has a lattice constant which is different from the lattice constant of the top layer 4. For example, the second layer 8 can be a GeSi layer, such as a GeSi layer with a Ge concentration between about 70 and 60%, or an A_{III}-B_{V}-semiconductor layer. The thickness of the second layer 8 can be of several hundred nanometers.

FIGS. 3 to 5 show schematically an exemplary process flow of an inventive method according to a first embodiment of the inventive method. In accordance with a first step shown in FIG. 3, a silicon-on-insulator structure 10 or SOI-structure is fabricated. The silicon-on-insulator structure 10 can be fabricated for example by SIMOX or by Smart-cut® technology, resulting in a structure consisting of a carrier substrate 2, for instance of silicon, which is covered by a buried layer 3 of silicon dioxide and having on top a single-crystalline top layer 4 of silicon. As shown in FIG. 1, the top layer 4 and the buried layer 3 form an interface 6 therebetween.

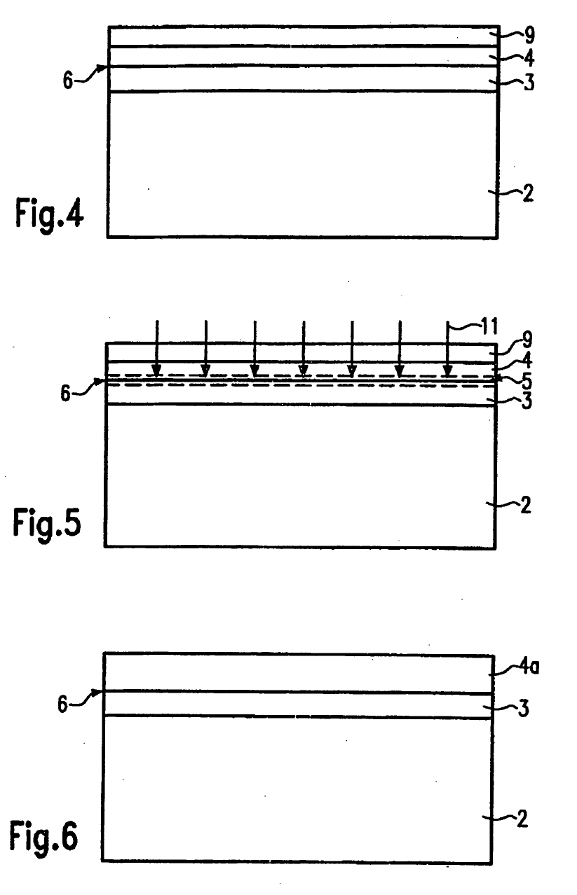

FIG. 4 shows the silicon-on-insulator structure of FIG. 3 after a further step in which an auxiliary layer 9 such as a silicon dioxide layer is deposited on the top layer 4. Any other material known in the art which can easily be deposited and then removed from the top layer 4 can be used Instead of silicon dioxide as auxiliary layer 9.

FIG. 5 shows the structure of FIG. 4 during a further step of the inventive method in which species 11, such as accelerated hydrogen ions, are implanted through the auxiliary layer 9 and the top layer 4 into a region 5 which is at or near the interface 6 between the top layer 4 and the buried layer 3. The species 1 which can form a layer of damages or microcavities in said region 5, causing a weakening of that region 5.

In this step, the implantation energy and/or the implantation depth may be so adjusted that a maximum or a peak of the implanted species is at or near an interface between the top layer 4 and the buried layer 3.

The implantation dose is preferably in a region of about 3×10¹⁶ H⁺-atoms/cm² or less so that blistering does not occur on the implanted surface, for instance, during later thermal treatments.

The implantation can be coupled with a thermal treatment of the implanted structure, for instance at temperatures between about 300° C. and about 1100° C. for approximately 1 hour.

FIGS. 6 to 8 show schematically an exemplary process flow of a second embodiment of the inventive method.

FIG. 6 shows schematically a side view of a silicon-on-insulator structure 10a, which has been fabricated in a first step. The silicon-on-insulator structure may be fabricated, for instance, by SIMOX or by Smart-cut® technology, resulting in a structure consisting of carrier substrate 2 such as a silicon substrate covered by a buried layer 3 of silicon dioxide having on top a thick single-crystalline top layer 4a of silicon with a thickness of about 500 nm. Preferably, the thick single-crystalline top layer 4 has a thickness of about several hundred nanometers. Between the top layer 4a and the buried layer 3 an interface 6 is formed.

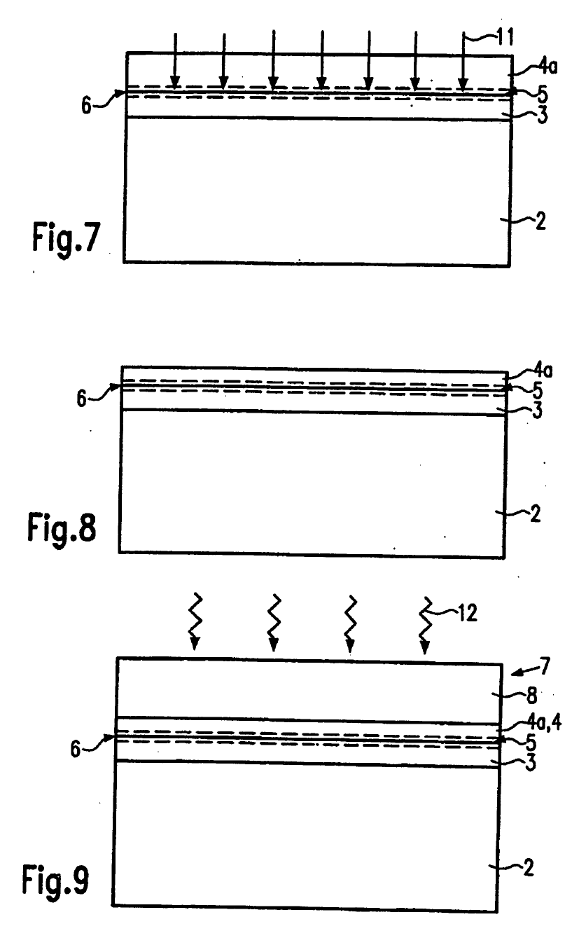

FIG. 7 shows the silicon-on-insulator structure 10a of FIG. 6 during an implantation step in which species 11 are implanted through the thick top layer 4a into a relatively thin region 5 at or near the interface 6 between the thick top layer 4a and the buried layer 3. The implanted species 11 are, for example, hydrogen ions which are accelerated with an energy of about 40 keV and which have a dose of about 3×10¹⁶H⁺/cm². The implanted species 11 concentrate in said thin regions and cause the generation of damages or microcavities in said region 5, resulting in a weakening of the material in that region 5.

The region 5 and in particular the interface 6 between the top layer 4a and the buried layer 3 is used to gather the implanted species 11. Therefore, the damaged implanted area is concentrated over the thin thickness of region 5 which improves compliance of the resulting compliant substrate.

FIG. 8 shows the structure of FIG. 7 after a thinning step in which the thick top layer 4a is thinned down to several tens of nanometers. For example, the thick top layer 4a of FIG. 7 can be oxidized and the oxidized part of the thick top layer 4a can be removed in an etching step during the thinning step. In another variant of the invention, the thick top layer 4a can be thinned down by using chemical-mechanical polishing or a combination of an abrasive method and an etching method.

With reference to FIG. 9, the structures shown in FIG. 5 or in FIG. 8, a second single-crystalline epitaxial layer 8 is grown, resulting in a heteroepitaxial structure 7 such as the structure 7 of FIG. 2. The material of the second layer 8 has a lattice constant which is different from the lattice constant of the top layer 4, 4a. For instance, the second layer, such as a GeSi layer with a Ge concentration of about 70 to 60%, can be a GeSi layer or an A_{III}-B_{V}-semiconductor. Because of the enhanced slippage effect between the top layer 4, 4a and the buried layer 3 at the interface 6 between these layers, the second layer 8 can be grown epitaxially on the top layer 4, 4a, with a low stress, resulting in a nearly defect-free growth of the second epitaxial layer 8 on the top layer 4, 4a. In this way, the second layer 8 can be grown with high quality up to a thickness of several hundred nanometers.

As shown by the arrows 12 in FIG. 9, the heteroepitaxial structure 7 is thermally treated after the growth of the second single-crystalline layer 8, resulting in a very good relaxation of the second layer 8.

In the above example, the second epitaxial layer 8 is grown on the compliant substrate 1 after implantation of the region 5 and/or region 13. In a further embodiment of the invention, the growth or deposition of the second epitaxial layer 8 can be carried out on a non-implanted substrate such as on the structure 10 shown in FIG. 3 followed by an implantation step through the second epitaxial layer 8 into the top layer 4 and/or the region 5 at or near the interface 6. In this case, the implantation can be made through the complete thickness of the second layer 8 or between several growth steps.

Preferably, the respective structure is annealed after an implantation step.

What is claimed is:

1. A method for making a compliant substrate for receiving a heteroepitaxial structure thereon, comprising:
providing a base structure that comprises a carrier substrate, a top single-crystalline layer that provides a top surface for the base structure, and a buried layer located between the carrier substrate and the top layer;
providing a weakened region in the top layer or between the top layer and the buried layer to form the compliant substrate; and
epitaxially growing an epitaxial layer on the compliant structure to form a heteroepitaxial structure.

2. The method of claim 1 wherein the weakened region forms an interface between the buried layer and the top layer.

3. The method of claim 1 wherein the weakened region is located in the top layer.

4. The method of claim 1 wherein the weakened region includes:
a first weakened region that forms an interface between the buried layer, and
a second weakened region located in the top layer.

5. The method of claim 1, wherein the weakened region is provided by implanting species into the compliant substrate.

6. The method of claim 5, wherein the species are implanted in the compliant substrate with an energy or depth of implanting that is adjusted in a manner such that a maximum concentrate of the species is implanted approximately at or near an interface between the buried layer and the top single-crystalline layer.

7. The method of claim 5, wherein the species include hydrogen or rare gas ions.

8. The method of claim 7, wherein the dose of the implanted species is about 3×10¹⁶ cm⁻².

9. The method of claim 5, wherein the species are implanted through the top single-crystalline layer and the method further comprises thinning the single-crystalline top layer to form the top surface.

10. The method of claim 9, wherein the thinning step comprises oxidizing or etching of the single-crystalline top layer.

11. The method of claim 1, which further comprises providing at least one auxiliary layer on the top single-crystalline layer prior to the weakening step.

12. The method of claim 11, wherein the auxiliary layer is provided by depositing silicon dioxide.

13. The method of claim 1, wherein the preparing of the base structure comprises fabricating a silicon-on-insulator structure.

14. The method of claim 1, wherein the epitaxial layer comprises a second single-crystalline epitaxial layer on the top single-crystalline layer, wherein the second single-crystalline epitaxial layer is made of a second material that is lattice mismatched with the single-crystalline top layer to form a heteroepitaxial structure thereon.

15. The method of claim 14, which further comprises annealing the heteroepitaxial structure.

16. A method for making a wafer with a heteroepitaxial structure thereon, comprising:
providing a base structure that comprises a carrier substrate, a top single-crystalline layer that provides a top surface for the base structure, and a buried layer located between the carrier substrate and the top layer;
implanting species into the top surface to provide a weakened region in the top layer or between the top layer and the buried layer to form the compliant substrate;
epitaxially growing an epitaxial layer on the compliant structure to provide a heteroepitaxial structure; and.
relaxing the heteroepitaxial structure by annealing the heteroepitaxial structure.

17. A method for making a compliant substrate for receiving a heteroepitaxial structure thereon, comprising:
providing a base structure that comprises a carrier substrate, a top single-crystalline layer that provides a top surface for the base structure, and a buried layer located between the carrier substrate and the top layer, and an auxiliary layer of silicon dioxide on the top layer;
providing a weakened region in the top layer or between the top layer and the buried layer to form the compliant substrate; and
thereafter epitaxially growing an epitaxial layer on the compliant structure to form a heteroepitaxial structure.
